(19) United States
(12) Patent Application Publication
(10) Pub. No.: US 2014/0238726 A1
(43) Pub. Date: Aug. 28, 2014

(54) EXTERNAL MOISTURE BARRIER PACKAGE FOR CIRCUIT BOARD ELECTRICAL COMPONENT

(71) Applicant: Cooper Technologies Company, Houston, TX (US)

(72) Inventors: Hundi Panduranga Kamath, Los Altos, CA (US); Kyle Yun-Su Kim, Manteca, CA (US); Cyrus Sam Rustomji, Walnut Creek, CA (US)

(21) Appl. No.: 13/779,932

(22) Filed: Feb. 28, 2013

(51) Int. Cl. H05K 5/06; H01G 2/10

(52) U.S. Cl. CPC H05K 5/065; H01G 2/103
USPC 174/251

(57) ABSTRACT

Moisture barrier packages for electrical components mountable to a circuit board include a cover and a base configured to provide a metal to metal joint that hermitically seals an electrical component in an enclosure defined by the cover and the base. The base may include patterned metallizations using circuit board printing techniques that facilitate connection of the electrical component to the circuit board. The base of the moisture barrier package may be configured for surface mounting of the electrical component or through-hole mounting to complete the electrical connection to the board through the base.

### BACKGROUND OF THE INVENTION

The field of the invention relates generally to electrical components for circuitry on a circuitry board, and more specifically to moisture barrier packages for electrical components subject to harsh operating environments.

A variety of electrical components are known that are adapted to be mounted to a circuit board. Such electrical components may include surface mount terminals or terminal leads that may be through-hole mounted to circuitry on a circuitry board. Certain types of electrical components are sensitive to environmental factors such as humidity, and accordingly attempts have been made to protect such sensitive components from humidity and moisture, for example. One example of such a sensitive electrical component is an electric double layer capacitor, sometimes referred to as a supercapacitor. The expected life of a supercapacitor may be considerably shortened if operated in environments having high humidity.

Accordingly, efforts have been made to moisture-proof electrical component packages for supercapacitors. Techniques such as metallized glass seals, polymer or copolymer seals, weldable seals, and metallized ceramic seals have been utilized to some extent as integral features in the electrical component construction of sensitive electrical components. Such sealing techniques can result in complicated component constructions and relatively expensive manufacture of the components. To some extent such sealing techniques can also be unreliable. More cost effective and reliable solutions are desired.

### BRIEF DESCRIPTION OF THE DRAWINGS

Non-limiting and non-exhaustive embodiments are described with reference to the following Figures, wherein like reference numerals refer to like parts throughout the various drawings unless otherwise specified.

FIG. 1 is a side elevational view of an exemplary electrical component for a circuit board.

FIG. 2 is a perspective of the component shown in FIG. 1 in combination with an external moisture barrier package according to a first exemplary embodiment of the present invention.

FIG. 3 is a sectional view of the moisture barrier package shown in FIG. 2.

FIG. 4 is a first side view of a base for the moisture barrier package shown in FIGS. 2 and 3.

FIG. 5 is a second side view of a base shown in FIG. 4.

FIG. 6 is a sectional view of a second exemplary embodiment an external moisture barrier package according to the present invention in combination with another exemplary electrical component for a circuit board.

FIG. 7 is a first side view of a base for the moisture barrier package shown in FIG. 6.

### DETAILED DESCRIPTION OF THE INVENTION

Exemplary embodiments of moisture barrier packages are described hereinbelow that may be utilized in combination with electrical components for circuit boards to protect sensitive electrical components for harsh operating environments including humid environments. Method aspects will be in part apparent and in part explicitly discussed in the following description.

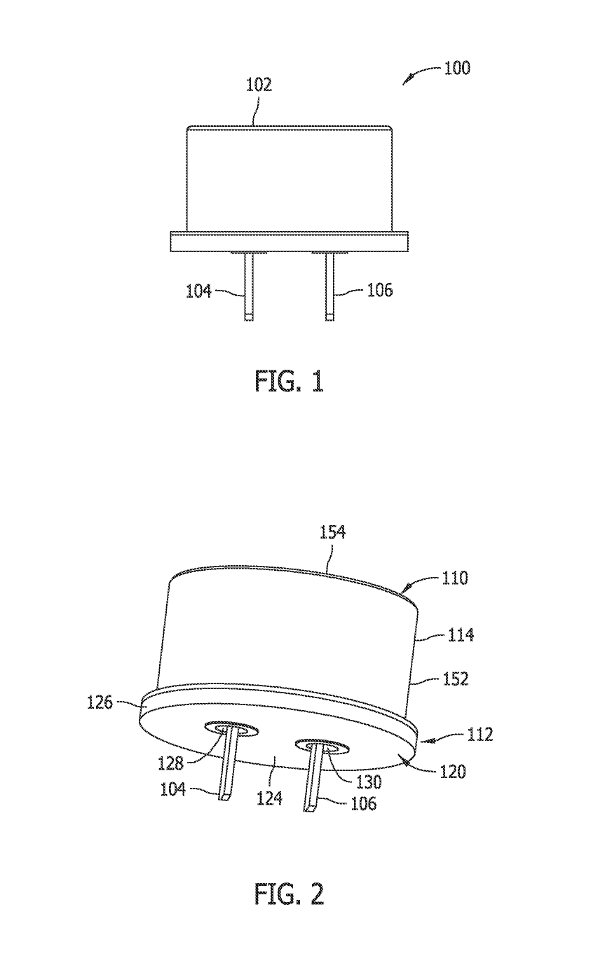

FIG. 1 is a side elevational view of an exemplary electrical component 100 for a circuit board. The component 100 includes a housing 102 and first and second electrical leads 104, 106 extending from the housing 102 for through-hole mounting to a circuit board.

In one embodiment, the component 100 is an electrochemical energy storage device, and more specifically, is an electric double layer capacitor (EDLC) device that may be used as a secondary source of current make it possible to accumulate, store and release electrical power to a circuit of the circuit board.

EDLC devices, sometimes referred to as a supercapacitors, typically have specific capacitance of greater than 100 F/g, as opposed to conventional capacitors with specific capacitance on the order of only several F/g. Supercapacitors are used in a variety of different applications such as memory backup to bridge short power interruptions, battery management applications to improve the current handling of a battery, or to provide a current boost on high load demands. As those in the art would appreciate, and like conventional EDLC devices, the ELDC device includes at least one storage cell internal to the housing 102. The storage cell is filled with an electrolyte and includes a positive electrode (cathode) and a negative electrode (anode) placed inside the housing, a separator such as a membrane that separates the anode space from the cathode space, and the lead terminals 104, 106 coupling the supercapacitor to a circuit board. One of the lead terminals 104 and 106 provides electrical connection to the anode when connected to circuitry on a circuit board, and the other of the lead terminals 104 and 106 provides electrical connection to the cathode when connected to circuitry on a circuit board

The construction and operation of the storage cell in the housing 102 of the EDLC device 100 is well understood and will not be detailed further herein, except to note that the EDLC device is particular sensitive to humidity and its operable life can be considerably shortened if not adequately protected. As such, and as noted above, efforts have been directed to sealing of the housing 102, both to prevent leakage of the electrolyte and to prevent the passage of moisture into the cell. Such sealing features can be somewhat elaborate and involved, presenting manufacturing difficulties and reliability issues as well as increased costs to the manufacture of the component 100.

FIG. 2 is a perspective view of the component 100 shown in FIG. 1 in combination with an external moisture barrier package 110 according to a first exemplary embodiment of the present invention. The moisture barrier package 110 is external to the component 100 and thus may be provided at relatively low cost while still providing moisture protection to the electrical component 100. The moisture barrier package 110 may be provided in lieu of or in addition to sealing features for the electrical component housing 102 (FIG. 1) to prevent ingress of moisture into the housing 102, even in high humidity operating environments.

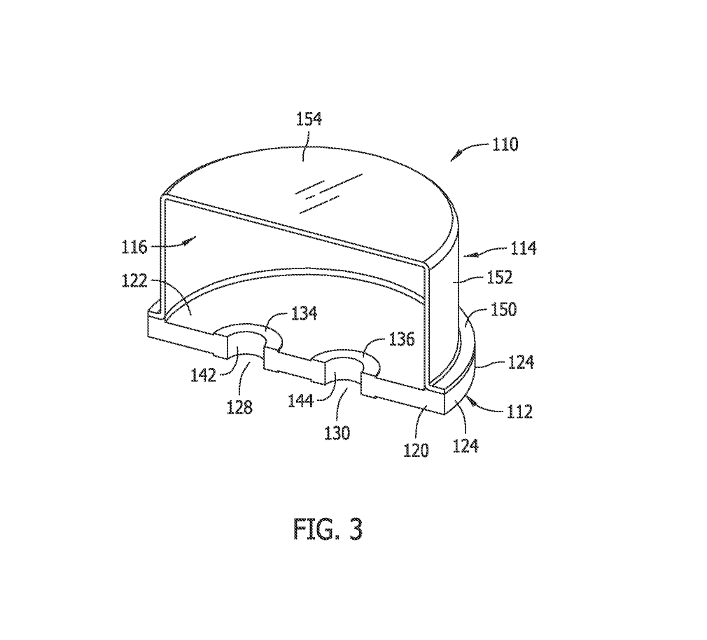

The moisture barrier package 110 includes a nonconductive base 112 and a cover 114. The leads 104, 106 of the component 100 (FIG. 1) are seen to protrude through the base 112 so that they may be connected to a circuit board using through-holes provided in the board and known techniques such as soldering. The cover 114 and base 112 collectively define an enclosure 116 (as best shown in FIG. 3 in sectional view) that is dimensioned to surround at least the housing 102 (FIG. 1) of the electrical component 100.

Referring now to FIGS. 2-5, the base 112 includes a round body 120 that is generally flat and planar, and in the example shown the body 120 has opposing major side surfaces 122 and 124 and a generally cylindrical outer edge wall 126. The major side surfaces 122, 124 are generally planar and circular, although other geometric shapes are possible. The diameter of the major side surfaces 122, 124 is much greater than a thickness dimension of the body 120 measured in a direction perpendicular to the major sides 122, 124. The body 112 defining the base 112 may be fabricated form a printed circuit board substrate material or a ceramic material in exemplary embodiments, although other materials are possible and may be utilized.

The body 120 of the base 112 also includes a pair of through-holes 128, 130 extending perpendicular to the planes of the major side surfaces 122, 124 and completely through the body 120. The through-holes 128, 130 are arranged diametrically in a spaced apart relation to one another and provide respective passageways through the body 120 for the respective leads 104, 106 (FIGS. 1 and 2) of the electrical component 100.

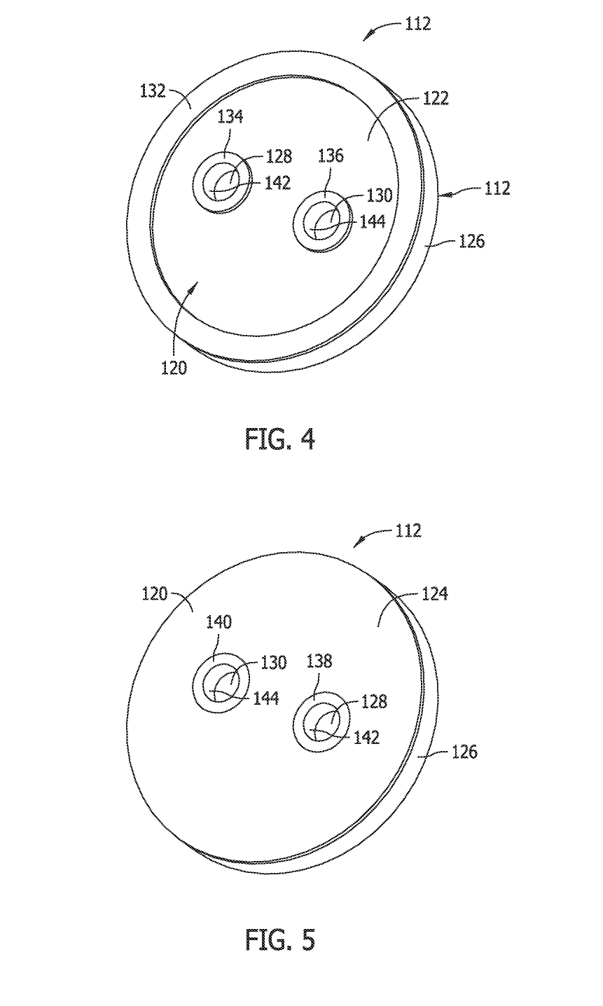

As shown in FIGS. 3 and 4, the major side 122 of the body 120 also includes a metallized pattern 132 formed on the surface thereof and extending around the outer periphery thereof. The metallized pattern 132 is formed using printed circuit board techniques in one example, and extends annularly around the major side 122 of the body 120 near its outer edge adjacent the cylindrical outer edge wall 126. The metallized pattern 132 extends as a thin band of metal material extending a complete 360° revolution on the major side 122. In other words, the metallized pattern 132 extends around the entire outer periphery of the major side 130.

Metallized patterns 134, 136 are also formed on the surface of the major side 122, also using printed circuit board techniques to form conductive traces on a surface of the body 120. The metallized patterns 134, 136 extend around the peripheries of the through-holes 128, 130 on the major side 122. As the through-holes 128, 130 are circular in cross section in the depicted embodiment, the metallized patterns 134, 136 extend as annular bands around the periphery of the through-holes 128, 130.

The major side 124, opposite the major side 122, as best seen in FIG. 5, includes metallized patterns 138, 140 formed on the surface of the major side 124. The patterns 138, 140 may be formed utilizing printed circuit board techniques to form conductive traces on a surface of the body 124. The metallized patterns 138, 140 extend around the peripheries of the through-holes 128, 130 on the major side 124. As the through-holes 128, 130 are circular in cross section in the depicted embodiment, the metallized patterns 138, 140 extend as annular bands around the periphery of the through-holes 138, 140. Unlike the major side 122 (FIG. 4), the major side 124 does not include the larger metallized pattern 132 on the outer periphery of the body 120. Rather, the surface of the major side 124 includes only the metallized patterns 138, 140 and the remainder of the surface of the major side 124 is free of any metallization.

The through-holes 128, 130 also respectively include metallized sidewalls 142, 144 extending perpendicular to the planes of the major sides 122, 124. The metallized sidewalls 142, 144 respectively extend between the metallized patterns 134, 136 on the first major side 122 and the metallized patterns 138, 140 on the second side. The metallized pattern 134, the metallized wall 142, and the metallized pattern 138 facilitate electrical connection of the lead 104 of the component 100 to the circuit board. The metallized pattern 136, the metallized wall 144, and the metallized pattern 140 facilitate electrical connection of the lead 106 of the component 100 to the circuit board. In different embodiments, the component 100 may be pre-attached to the base 112 and provided for assembly to the circuit board, the base 112 may be pre-attached to the circuit board for subsequent mounting of the component 100 via the leads 104 and 106, or the base 112 and the component 112 may be simultaneously mounted to a circuit board.

The cover 114 in the exemplary embodiment shown in FIGS. 2 and 3 includes a peripheral annular flange or lip 150 extending horizontally in FIGS. 2 and 3, and a sidewall 152 extending vertically upwardly and away from the lip 150. A top wall 154 extends across an upper edge of the sidewall 152. The annular flange or lip 150 extends annularly as a thin band around the periphery of the base 112, and is shown in the Figures to overlie the metallized pattern 132 (FIG. 4) of the base 112.

In one embodiment, the cover 114, including the flange 150 is fabricated from metal, thereby providing a metallic periphery via the flange 150 that may joined to the metallized pattern 132 via soldering or welding, for example, and creating a hermetic seal between the cover 114 and the base 112. In another embodiment, the flange 140 of the cover 114 may be metallic, while the sidewall 152 and the top wall 154 may be fabricated from another non-metallic material while still providing similar benefits.

The sidewall 152 of the cover 114 is rounded or cylindrical and is inset from the flange 150 in the example shown. That is, an outer radius of the sidewall 152 is less than the outer radius of the flange 150, and the outer radius of the flange 150 is about equal to the radius of the base 112. The top wall 154 extends over the sidewall 152 and is oriented generally parallel to major side 122 of the base 112. The sidewall 152 and top wall 152 are relatively thin and define a hollow interior cavity corresponding to the enclosure 116 shown in FIG. 2. The enclosure 116 is larger than the housing 102 of the component 100 to be protected therein, such that when the component 100 is installed in the enclosure 116 the cover sidewall 152 and the cover top wall 152 surround the component housing 102 but are spaced from the outer surfaces of the component housing 102. As such, the cover 114 extends external to and is spaced from the component housing 102 inside the package 110.

The base 112 and the cover 114 may be separately fabricated from the component 100 and provided for assembly into the moisture barrier package 110. In one embodiment, the base 112 and the cover 114 may be provided in kit form for assembly over the component 100 by a component manufacturer or an end purchaser of the component. In another embodiment, the moisture barrier package 110 may be provided to an end user with the component 100 packaged therein and ready for mounting to a circuit board. In still another embodiment, the package 110 may be assembled as the component 100 is installed to the circuit board.

To assemble the package 110, the leads 104, 106 of the component 100 may be extended through the through-holes 128, 130 in the base 112 as shown in FIG. 2. The cover 114 may then be assembled to the base 112 over the component 112, and the metallized pattern 132 of the base 112 may be joined with the metallic periphery of the cover 112 via the flange 150 to create a sealed metal to metal joint between the cover 112 and base 114 to protect the component 112 from moisture and humidity. Soldering or welding techniques may be used to create the metal to metal seal. The leads 104, 106 may then be installed to the circuit board using known techniques, with the package base 112 extending between the circuit board and the component housing 112, but with the leads 104, 106 extending through the through-holes 128, 130 to complete an electrical connection to the board through the base 112.

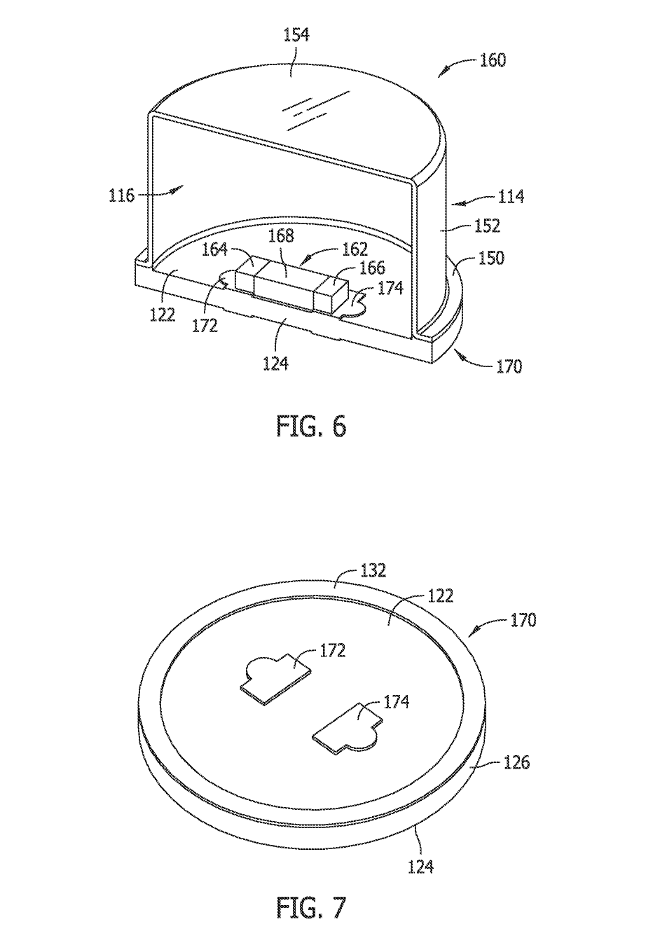

FIGS. 6 and 7 illustrate another embodiment of a moisture barrier package 160 that is in many aspects similar to the package 110 described above, but is adapted for protecting an electrical component 162 having surface mount terminals 164, 166 extending from opposing ends of a nonconductive housing 168. The component 162 may be an EDLC device as described above.

The moisture barrier package 160 includes the cover 114 as described above, in combination with a base 170 that is adapted for surface mounting of the component 162.

Like the base 112, the base 170 includes opposing major sides 122, 124 and an outer side wall 126. The metallized pattern 132 is provided on the major side 122 as described above that may be joined to create a metal to metal seal between the cover 114 and the base 112.

Instead of the through-holes 128, 130, however, the base 170 includes metallized patterns in the form of surface mount pads 172, 174 extending on surfaces of each of the major sides 122, 124 of the base 170. The surface mount pads 172, 174 may be formed using printed circuit board techniques on a surface of each major side 122, 124, and the surface mount pads on each side may be electrically connected by conductive vias extending through the base 170 between the major sides 122, 124. As such, the component 162 may be surface mounted to the side 122 of the base 170 via the terminals 164, 166 and the surface mount pads 172, 174 on the first major side 122 of the base, while the terminal mount pads on the second side 124 of the base 172 may be surface mounted to the printed circuit board to complete an electrical connection between the circuit board and the component 100 through the base 172.

Like the package 110, the base 170 and the cover 114 may be separately fabricated from the component 162 and provided for assembly into the moisture barrier package 160. In one embodiment, the base 170 and the cover 114 may be provided in kit form for assembly over the component 162 by a component manufacturer or an end purchaser of the component 162. In another embodiment, the moisture barrier package 160 may be provided to an end user with the component 100 packaged therein and ready for mounting to a circuit board. In still another embodiment, the package 160 may be assembled as the component 162 is installed to the circuit board.

To assemble the package 160, the surface mount terminals 164, 166 of the component 162 may be mounted to the terminal pads 172, 174 on the side 122 of the base 170. The base 170 may be mounted to a circuit board prior to surface mounting of the component 160 in some embodiments, or on other embodiments the component 162 may be mounted to the base 170 prior to the base 170 being mounted to the board. Regardless, the cover 114 is assembled to the base 170 over the component 162, and the metallized pattern 132 of the base 170 may be joined with the metallic periphery of the cover 112 via the flange 150 to create a sealed metal to metal joint between the cover 112 and base 114 to protect the component 160 from moisture and humidity. Soldering or welding techniques may be used to create the metal to metal seal.

The external moisture barrier packages 110 and 160 provide moisture-proof protection for components 100, 162 that may render certain sealing features into the component construction unnecessary. As such, potentially lower cost components 100, 162 may be utilized in the moisture-proof packages 110, 160 by avoiding more expensive sealing features that are internal to or provided integral with the components 100, 162.

Alternatively, to the extent that the packages 110, 160 are used in combination with components 100, 162 having integral sealing features to protect against ingress of moisture, the moisture-proof packages 110, 162 provide a fail-safe moisture protection feature. Even if the sealing features of the components 100, 162 used in the packages 110, 160 were compromised, the packages 110, 160 nonetheless provide moisture-proof protection of the components 100 or 162. Also, by virtue of dual moisture-proof provided by the packages 110 or 160 and also in the component construction of ELDC devices 100 of 162, if either were to fail the other will remain. It would be rather unlikely that both moisture-proof features would fail in such a scenario.

In the exemplary embodiments described, the moisture-proof packages 110, 160 are believed to be particular beneficial in protecting EDLC devices. Other types of electrical components for circuit boards may also benefit, however, from such moisture-proof protection. Such other electrical components may include, but are not limited to, circuit protection fuses and other power management and protection devices.

The bases 112, 170 and cover 114 in the packages 110, 160 described are manufacturable from widely available materials using relatively low cost techniques. The packages 110, 160 are also rather easily assembled and joined to provide moisture-proof protection in a low cost manner.

While exemplary shapes and geometry of components, bases and covers are described in the exemplary moisture-proof packages 110 and 160 described above, adaptations are of course possible. For example, while in the exemplary embodiments described the metallized periphery of the cover 112 is complementary in shape to the metallized pattern 136 on the package base (i.e. both are annular in the embodiments depicted) this is not strictly necessary and non-complementary shapes could be used so long as metal to metal joints could be created between the base and cover.

As another example of a contemplated adaptation, while round bases and cylindrical covers are shown and described for the exemplary moisture-proof packages 110 and 160, rectangular-shaped bases and rectangular metallized peripheries of covers (as well as other geometric shapes) may likewise be utilized with similar benefits and advantages so long as sealed metal to metal joints may be created between the base and cover.

As yet another example of a contemplated adaptation, while the enclosure 116 in the exemplary moisture-proof packages 110 and 160 is defined by the cover extending over flat and planar bases, other arrangements are possible. The enclosure could be defined in part in the base and in part in the cover in embodiments where a non-planar base is used with non-planar cover. Similarly, in another contemplated embodiment the enclosure could be defined predominately by the base with a planar cover element joined to the base. As long as the sealed metal to metal joints may be created between the base and cover, the particular shapes of the cover and base are not particularly important and various shapes may be utilized.

It is also contemplated that secondary covers may be utilized in combination with the cover 114 as described, particularly in embodiments wherein the cover 114 is fabricated entirely from metal. A secondary cover fabricated from a non-metal material may be provided and may overlie the cover 112.

The advantages and benefits of the inventive concepts are now believed to be evident in view of the exemplary embodiments disclosed.

An embodiment of a moisture barrier package for an electrical component adapted to be mounted to a circuit board has been disclosed. The electrical component includes a nonconductive housing and first and second conductive terminals for connection to the circuit board. The moisture barrier package includes a nonconductive base comprising a body and a metallized pattern formed on a surface of the body, and a cover comprising a metallic periphery. The cover and base collectively define an enclosure dimensioned to surround at least the housing of the electrical component, and the metallic periphery and the metallized pattern are configured to be joined to provide a hermetic seal between the cover and the base.

Optionally, the body of the base may be generally flat and planar. The flat and planar body may include opposing first and second major side surfaces, with the metallized pattern provided on one of the major side surfaces. The metallized pattern may be annular. First and second through-holes may be formed through the body, and peripheral metallized patterns may extend about the first and second-through holes. The first and second through-holes may be defined by internal side walls extending though the body of the base, with the internal side walls being metallized. At least one of the internal side walls may be cylindrical.

The base may be round, and at least one surface mount metallized pattern formed on the base may be configured to be joined with surface mount terminals of the electrical component. The base may be fabricated from a printed circuit board substrate material, or may be fabricated from a ceramic material.

The metal periphery of the cover may extend in a complementary manner to the metallized pattern formed on the base. The cover may further include a cylindrical side wall extending above the base.

An embodiment of an electrical component package has also been disclosed. The electrical component package includes: an electrical component comprising a nonconductive housing and first and second conductive terminals for establishing electrical connection to the circuit board; and a moisture-proof package comprising: a nonconductive base comprising a body and a metallized pattern formed on a surface of the body; and a cover comprising a metallic periphery; wherein the metallic periphery and the metallized pattern are joined to provide a hermetic seal between the cover and the base and wherein the cover and base collectively define an enclosure dimensioned to contain at least the housing of the electrical component therebetween.

Optionally, the body may be generally flat and planar. The flat and planar body may include opposing first and second major side surfaces, the peripheral metallized pattern provided on one of the major side surfaces. The peripheral metallized pattern may be annular. The first and second terminals of the electrical component may include first and second leads, and the base may include first and second through-holes formed through the body to receive the first and second leads. Peripheral metallized patterns may extend about the first and second-through holes. The first and second through-holes may be defined by internal side walls extending though the body of the base, the internal side walls being metallized. At least one of the internal side walls may be cylindrical. The base may be round. The first and second terminals of the electrical component may be surface mount terminals, and the base may include at least one surface mount metallized pattern formed on the base to establish electrical connection with the surface mount terminals.

The base may be fabricated from a printed circuit board substrate, or may be fabricated from a ceramic material. The cover may include an annular peripheral lip, and a cylindrical side wall extending above the base. The electrical component may be an electric double layer capacitor (EDLC) device.

An embodiment of an electrical component package is also disclosed including: an electrical component comprising a nonconductive housing adapted to be mounted to a circuit board via at least one of surface mount terminals and through-hole mounting leads, and a moisture-proof package separately fabricated from the electrical component, the moisture-proof package comprising: a nonconductive base comprising a body, a peripheral metallized pattern formed on the body, and means to complete an electrical connection from the electrical component to the circuit board through the base; and a cover comprising a metallic periphery complementary to the metallized pattern of the base; wherein the cover and base collectively define an enclosure extending external to and spaced from the housing of the electrical component; and wherein the metallic periphery and the metallized pattern are joined to provide a metal to metal hermetic seal between the cover and the base. The electrical component may be an electric double layer capacitor (EDLC) device.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A moisture barrier package for an electrical component adapted to be mounted to a circuit board, the electrical component comprising a nonconductive housing and first and second conductive terminals for connection to the circuit board, the moisture barrier package comprising:
a nonconductive base comprising a body and a metallized pattern formed on a surface of the body; and
a cover comprising a metallic periphery;
wherein the cover and base collectively define an enclosure dimensioned to surround at least the housing of the electrical component; and
wherein the metallic periphery and the metallized pattern are configured to be joined to provide a hermetic seal between the cover and the base.

2. The moisture barrier package of claim 1, wherein the body of the base is generally flat and planar.

3. The moisture barrier package of claim 2, wherein the flat and planar body comprises opposing first and second major side surfaces, the metallized pattern provided on one of the major side surfaces.

4. The moisture barrier package of claim 1, wherein the metallized pattern is annular.

5. The moisture barrier package of claim 1, further comprising first and second through-holes formed through the body.

6. The moisture barrier package of claim 5, further comprising peripheral metallized patterns extending about the first and second-through holes.

7. The moisture barrier package of claim 5, wherein the first and second through-holes are defined by internal side walls extending though the body of the base, the internal side walls being metallized.

8. The moisture barrier package of claim 7, wherein at least one of the internal side walls is cylindrical.

9. The moisture barrier package of claim 1, wherein the base is round.

10. The moisture barrier package of claim 1, further comprising at least one surface mount metallized pattern formed on the base configured to be joined with surface mount terminals of the electrical component.

11. The moisture barrier package of claim 1, wherein the base is fabricated from a printed circuit board substrate.

12. The moisture barrier package of claim 1, wherein the base is fabricated from a ceramic material.

13. The moisture barrier package of claim 1, wherein the metal periphery of the cover extends in a complementary manner to the metallized pattern formed on the base.

14. The moisture barrier package of claim 1, wherein the cover further comprises a cylindrical side wall extending above the base.

15. An electrical component package comprising:
an electrical component comprising a nonconductive housing and first and second conductive terminals for establishing electrical connection to the circuit board; and
a moisture-proof package comprising:
a nonconductive base comprising a body and a metallized pattern formed on a surface of the body; and
a cover comprising a metallic periphery;
wherein the metallic periphery and the metallized pattern are joined to provide a hermetic seal between the cover and the base and wherein the cover and base collectively define an enclosure dimensioned to contain at least the housing of the electrical component therebetween.

16. The electrical component package of claim 14, wherein the body is generally flat and planar.

17. The electrical component package of claim 15 wherein the flat and planar body comprises opposing first and second major side surfaces, the peripheral metallized pattern provided on one of the major side surfaces.

18. The electrical component package of claim 14, wherein the peripheral metallized pattern is annular.

19. The electrical component package of claim 14, wherein the first and second terminals of the electrical component comprise first and second leads, and the base comprises first and second through-holes formed through the body to receive the first and second leads.

20. The electrical component package of claim 18, further comprising peripheral metallized patterns extending about the first and second-through holes.

21. The electrical component package of claim 14, wherein the first and second through-holes are defined by internal side walls extending though the body of the base, the internal side walls being metallized.

22. The electrical component package of claim 20, wherein at least one of the internal side walls is cylindrical.

23. The electrical component package of claim 14, wherein the base is round.

24. The electrical component package of claim 14, wherein the first and second terminals of the electrical component comprise surface mount terminals, and the base comprises at least one surface mount metallized pattern formed on the base to establish electrical connection with the surface mount terminals.

25. The electrical component package of claim 14, wherein the base is fabricated from a printed circuit board substrate.

26. The electrical component package of claim 14, wherein the base is fabricated from a ceramic material.

27. The electrical component package of claim 14, wherein the cover comprises an annular peripheral lip.

28. The electrical component package of claim 14, wherein the cover further comprises a cylindrical side wall extending above the base.

29. The electrical component package of claim 14, wherein the electrical component is an electric double layer capacitor (EDLC) device.

30. An electrical component package comprising:
an electrical component comprising a nonconductive housing adapted to be mounted to a circuit board via at least one of surface mount terminals and through-hole mounting leads, and
a moisture-proof package separately fabricated from the electrical component, the moisture-proof package comprising:
a nonconductive base comprising a body, a peripheral metallized pattern formed on the body, and means to complete an electrical connection from the electrical component to the circuit board through the base; and
a cover comprising a metallic periphery complementary to the metallized pattern of the base;
wherein the cover and base collectively define an enclosure extending external to and spaced from the housing of the electrical component; and
wherein the metallic periphery and the metallized pattern are joined to provide a metal to metal hermetic seal between the cover and the base.

31. The electrical component package of claim 29, wherein the electrical component is an electric double layer capacitor (EDLC) device.
